(19) United States
(12) Patent Application Publication
(10) Pub. No.: US 2025/0157958 A1
(43) Pub. Date: May 15, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Jongkook KIM, Suwon-si (KR); Heungkyu KWON, Suwon-si (KR); Junghwan JANG, Yishun (SG); Youngcheol KIM, Yishun (SG); Daehyun KIM, Suwon-si (KR); Choonheung LEE, Yishun (SG); Kwangho LEE, Suwon-si (KR); Hangchul CHOI, Yishun (SG)

(73) Assignees: Samsung Electronics Co., Ltd., Suwon-si (KR); STATS ChipPAC Pte. Ltd., Singapore (SG)

(21) Appl. No.: 18/947,424

(22) Filed: Nov. 14, 2024

(30) Foreign Application Priority Data
Nov. 15, 2023 (SG) 10202303230P

(51) Int. Cl. H01L 23/00; H01L 21/56; H01L 23/498; H01L 25/18; H10B 80/00

(52) U.S. Cl. CPC H01L 24/04; H01L 21/565; H01L 23/49838; H01L 24/03; H01L 24/05; H01L 24/16; H01L 23/49833; H01L 25/18; H01L 2224/03464; H01L 2224/03622; H01L 2224/0401; H01L 2224/05005; H01L 2224/05083; H01L 2224/05541; H01L 2224/05557; H01L 2224/05573; H01L 2224/05582; H01L 2224/05583; H01L 2224/16227; H01L 2224/16238; H01L 2924/1815; H10B 80/00

(57) ABSTRACT

A semiconductor package and a method of manufacturing the semiconductor package are provided. The semiconductor package includes an interposer, a semiconductor chip on the interposer, an under bump metal (UBM) pad between the interposer and the semiconductor chip and including an upper UBM pad and a lower UBM pad, and a connection member between the UBM pad and the semiconductor chip, wherein the connection member is in contact with one or more side surfaces of the UBM pad and is in contact with the interposer.

### CROSS-REFERENCE TO RELATED APPLICATION

This application is based on and claims priority under 35 U.S.C. § 119 to Singapore Patent Application No. 10202303230P, filed on Nov. 15, 2023, in the Intellectual Property Office of Singapore (IPOS), the disclosure of which is incorporated by reference herein in its entirety.

### BACKGROUND

The inventive concepts relate to semiconductor packages and methods of manufacturing the semiconductor packages, and more particularly, to semiconductor packages including an interposer and methods of manufacturing the semiconductor packages.

In accordance with the rapid development of the electronics industry and user demands, electronic devices have become more compact and multi-functional.

### SUMMARY

Some example embodiments of the inventive concepts provide a semiconductor package with improved electrical characteristics and a method of manufacturing the semiconductor package. Some example embodiments may provide a semiconductor package having fine pitch connection terminals and fine-sized electrode pads to mount high-capacity semiconductor chips within a limited structure of a semiconductor package to thereby enable increased miniaturization and/or multi-functionality of semiconductor chips, semiconductor packages including same, and/or electronic devices including same without compromising electrical characteristics thereof (e.g., electrical connections, electrical contact areas, etc.). Such semiconductor packages, according to some example embodiments, may have a structure that electrically connects a connection terminal, among fine pitch connection terminals, to a fine-sized electrode pad among the fine-sized electrode pads of the semiconductor package. Some example embodiments may provide a method for electrically connecting a connection terminal, among fine pitch connection terminals of a semiconductor package, to a fine-sized electrode pad among fine-sized electrode pads of the semiconductor package. Such semiconductor packages and methods of manufacturing same may enable increased miniaturization and multi-functionality of semiconductor chips based on providing semiconductor packages having fine pitch connection terminals and fine-sized electrode pads with improved electrical characteristics.

The technical problems to be solved by the inventive concepts are not limited to the problems mentioned above, and other problems not mentioned will be clearly understood by those skilled in the art from the description below.

According to some example embodiments of the inventive concepts, a semiconductor package may include an interposer, a semiconductor chip on the interposer, an under bump metal (UBM) pad between the interposer and the semiconductor chip and including an upper UBM pad and a lower UBM pad, and a connection member between the UBM pad and the semiconductor chip. The connection member may be in contact with one or more side surfaces of the UBM pad and may be in contact with the interposer.

According to some example embodiments of the inventive concepts, a method of manufacturing a semiconductor package may include forming an interposer, forming a UBM pad on the interposer, forming a plating layer on the UBM pad, and attaching a connection member onto the UBM pad, wherein the plating layer is in contact with one or more side surfaces of the UBM pad.

According to some example embodiments of the inventive concepts, a method of manufacturing a semiconductor package may include forming an interposer, forming a UBM pad on the interposer, mounting a semiconductor chip on the UBM pad, and forming a molding layer on the interposer, wherein the mounting of the semiconductor chip on the UBM pad may include forming a plating layer on the UBM pad, and attaching a connection member onto the UBM pad. The plating layer may be in contact with one or more side surfaces of the UBM pad.

### BRIEF DESCRIPTION OF THE DRAWINGS

Example embodiments will be more clearly understood from the following detailed description taken in conjunction with the accompanying drawings in which:

FIG. 1 is a cross-sectional view illustrating a semiconductor package according to some example embodiments;

FIG. 2 is an enlarged cross-sectional view of area A of FIG. 1, according to some example embodiments;

FIG. 3 is an enlarged cross-sectional view of area A of FIG. 1, according to some example embodiments;

FIG. 4 is an enlarged cross-sectional view of area A of FIG. 1, according to some example embodiments;

FIG. 5 is an enlarged cross-sectional view of area A of FIG. 1, according to some example embodiments;

FIG. 6 is an enlarged cross-sectional view of area A of FIG. 1, according to some example embodiments;

FIG. 7 is an enlarged cross-sectional view of area A of FIG. 1, according to some example embodiments;

FIGS. 8, 9, 10, 11, 12, 13, 14, and 15 are cross-sectional views illustrating a method of manufacturing a semiconductor package, according to some example embodiments; and

FIG. 16 is a schematic view of an electronic device according to some example embodiments.

### DETAILED DESCRIPTION

Hereinafter, some example embodiments of the inventive concepts will be described in detail with reference to the attached drawings. To clearly describe the present inventive concepts, parts that are irrelevant to the description in the drawings are omitted. The same reference numerals are used for the same components in the drawings, and redundant descriptions thereof are omitted. Further, since sizes and thicknesses of constituent members shown in the accompanying drawings are arbitrarily given for better understanding and ease of description, the present inventive concepts are not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, plate, etc. is referred to as being “on” another element, it can be directly on the other element or intervening elements may also be present. In contrast, when an element is referred to as being “directly on” another element, there are no intervening elements present. Further, in the specification, the word “on” or “above” means positioned on, below, or horizontally adjacent to the object portion and does not necessarily mean positioned on the upper side of the object portion based on a gravitational direction.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that surfaces which may be referred to as being “flat” may be understood to be “planar” or “substantially planar.” It will be understood that surfaces which may be referred to as being “planar” may be “planar” or may be “substantially planar.” Surfaces that are “substantially planar” will be understood to be “planar” within manufacturing tolerances and/or material tolerances and/or have surface portions with a deviation in magnitude and/or angle from “planar,” respectively, with regard to the other portions of the surfaces that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

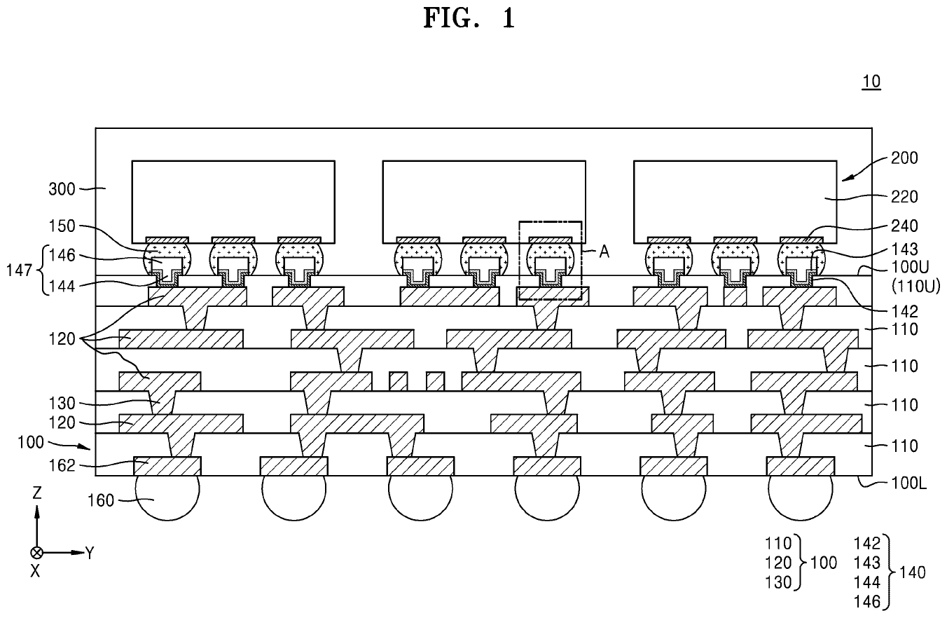

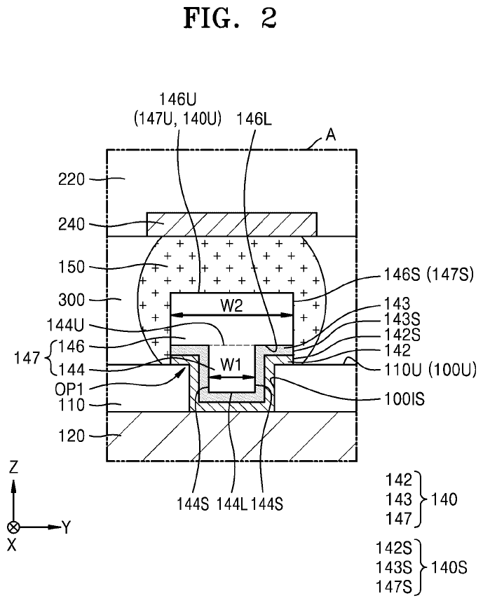

FIG. 1 is a cross-sectional view illustrating a semiconductor package 10 according to some example embodiments. FIG. 2 is an enlarged cross-sectional view of area A of FIG. 1 according to some example embodiments.

Referring to FIGS. 1 and 2, the semiconductor package 10 includes an interposer 100, an under bump metal (UBM) structure 140, a connection member 150, an external connection terminal 160, a semiconductor chip 200, and a molding layer 300.

When the semiconductor chip 200 is miniaturized and/or the number (e.g., quantity) of input/output terminals increases, the semiconductor package 10 has a limitation in accommodating all external connection terminals 160 which are input/output terminals within a main surface of the semiconductor chip 200. Therefore, a Fan-Out Wafer Level Package (FO-WLP) or Fan-Out Panel Level Package (FO-PLP) structure including the external connection terminal 160 is applied to the semiconductor package 10 by extending the interposer 100 to the molding layer 300 that forms (e.g., at least partially defines) an outer circumferential surface of the semiconductor chip 200.

In addition, the semiconductor package 10 among FO packages may be implemented using a chip-last manufacturing method of firstly forming the interposer 100 on a carrier substrate, and then mounting the semiconductor chip 200 on the formed interposer 100.

The interposer 100 may electrically connect different semiconductor chips 200 to each other. In some example embodiments, including the example embodiments shown in FIGS. 1-15, the interposer 100 is shown as a redistribution layer (RDL) interposer, also referred to herein interchangeably as a redistribution structure interposer 100, but the interposer 100 may include various types of interposers, such as a silicon interposer and/or an organic interposer. Hereinafter, example embodiments where the interposer 100 is an RDL interposer, that is, a redistribution structure interposer 100, will be described according to some example embodiments, but it will be understood that descriptions relating to the RDL interposer (e.g., descriptions relating to the redistribution structure interposer 100) may apply equally to an interposer of a semiconductor package 10 according to any of the example embodiments, including applying equally to other types of interposers, including a silicon interposer and/or an organic interposer.

The redistribution structure interposer 100 may be disposed on (e.g., disposed at) a lower portion of the semiconductor package 10. The redistribution structure interposer 100 may transmit an electrical signal of the semiconductor chip 200 to the external connection terminal 160. In some example embodiments, the redistribution structure interposer 100 may transmit an electrical signal received by the external connection terminal 160 to the semiconductor chip 200. In some example embodiments, the redistribution structure interposer 100 may transmit electrical signals between different semiconductor chips 200 (e.g., between different semiconductor chips of the same semiconductor package 10 or different semiconductor packages 10). The redistribution structure interposer 100 may electrically connect different semiconductor chips 200 to each other.

The redistribution structure interposer 100 may be an RDL interposer that may include a redistribution insulating layer 110, a redistribution line pattern 120, and a redistribution via pattern 130. The redistribution structure interposer 100 may be formed as a single metal wiring layer or multiple metal wiring layers. For example, the redistribution structure interposer 100 may include copper (Cu), nickel (Ni), gold (Au), chromium (Cr), titanium (Ti), or palladium (Pd), or any alloy thereof. In some example embodiments, the redistribution structure interposer 100 may be formed using an electroplating process.

The redistribution insulating layer 110 may be formed as a single layer or multiple layers, for example as shown in FIG. 1. As shown, the redistribution insulating layer 110 may include a plurality of redistribution insulating layers 110 which may be stacked in the vertical direction (Z direction). The plurality of redistribution insulating layers 110 may be collectively referred to herein interchangeably as the redistribution insulating layer 110, and it will be understood that descriptions of the redistribution insulating layer 110 as described herein may apply equally to the plurality of redistribution insulating layers 110. It will be understood that an upper surface 110U of the redistribution insulating layer 110 may be an upper surface of an uppermost redistribution insulating layer 110 among a plurality of redistribution insulating layers 110 stacked in the vertical direction (Z direction). The redistribution insulating layer 110 may include an insulating material, for example, photo-imageable dielectric (PID) resin, and may further include photosensitive polyimide and/or an inorganic filler. All layers of the redistribution insulating layer 110 may include the same material, or at least one layer thereof may include a different material.

Although not shown in FIGS. 1 and 2, the semiconductor package 10 may further include a protective layer that protects pads on an upper surface 100U and/or a lower surface 100L of the redistribution structure interposer 100.

The redistribution line pattern 120 and the redistribution via pattern 130 may transmit electrical signals and/or heat within the redistribution structure interposer 100. As shown, the redistribution line pattern 120 may include a plurality of redistribution line patterns 120 which may be arranged (e.g., spaced apart) in the vertical direction (Z direction), for example on separate, respective upper surfaces of separate, respective redistribution insulating layers 110. The plurality of redistribution line patterns 120 may be collectively referred to herein interchangeably as the redistribution line pattern 120, and it will be understood that descriptions of the redistribution line pattern 120 as described herein may apply equally to the plurality of redistribution line patterns 120. The redistribution line pattern 120 may be formed inside the redistribution insulating layer 110 and may extend in a horizontal direction (X direction and/or Y direction). As shown, the redistribution via pattern 130 may include a plurality of redistribution via patterns 130 which may be arranged (e.g., spaced apart) in the vertical direction (Z direction), for example on separate, respective lower surfaces of separate, respective redistribution line patterns 120 and extending through separate, respective redistribution insulating layers 110. The plurality of redistribution via patterns 130 may be collectively referred to herein interchangeably as the redistribution via pattern 130, and it will be understood that descriptions of the redistribution via pattern 130 as described herein may apply equally to the plurality of redistribution via patterns 130. The redistribution via pattern 130 (e.g., a given redistribution via pattern 130) may electrically connect the redistribution line patterns 120 (e.g., vertically adjacent redistribution line patterns 120) spaced apart in a vertical direction (Z direction) and may extend in the vertical direction (Z direction). The redistribution line pattern 120 and the redistribution via pattern 130 may each include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or any alloy thereof, but are not limited thereto. As shown, a given redistribution via pattern 130 and a given redistribution line pattern 120 may be defined by separate portions of a single, unitary piece of material.

While some example embodiments of the redistribution structure interposer 100 are described herein to include a redistribution line pattern 120 and a redistribution via pattern 130, it will be understood that an interposer 100 of various types may include a plurality of conductive line patterns and a plurality of conductive via patterns, and the plurality of conductive via patterns each have a tapered shape with a horizontal width decreasing with increasing distance from the semiconductor chip 200. In example embodiments where the interposer is a redistribution structure interposer 100 as shown, the plurality of conductive line patterns may include the redistribution line pattern 120 and the plurality of conductive via patterns may include the redistribution via pattern 130. It will be understood that descriptions herein of a redistribution line pattern 120 of a redistribution structure interposer 100 may apply equally to a conductive line pattern of an interposer according to some example embodiments. It will be understood that descriptions herein of a redistribution via pattern 130 of a redistribution structure interposer 100 may apply equally to a conductive via pattern of an interposer according to some example embodiments.

The redistribution line pattern 120 and the redistribution via pattern 130 may be formed using a plating method. For example, the redistribution line pattern 120 and the redistribution via pattern 130 may be formed using a plating method such as immersion plating, electroless plating, or electroplating.

In some example embodiments, a plurality of redistribution via patterns 130 may each have a tapered shape with a horizontal width decreasing and extending from the top to the bottom. That is, the plurality of redistribution via patterns 130 may each have a horizontal width in one or more horizontal directions (e.g., X direction and/or Y direction) decreasing with increasing distance of the horizontal width further away from the semiconductor chip 200 in the vertical direction (Z direction), for example such that the horizontal width tapers with increasing proximity to a lower surface 100L of the redistribution structure interposer 100 in the vertical direction and/or with increasing distance from an upper surface 100U of the redistribution structure interposer 100 in the vertical direction.

In the specification, a direction parallel or substantially parallel to the main surface of the redistribution structure interposer 100 may be referred to as the horizontal direction (X direction and/or Y direction), and a direction perpendicular or substantially perpendicular to the horizontal direction (X direction and/or Y direction) may be referred to as the vertical direction (Z direction). The main surface of the redistribution structure interposer 100 may be the upper surface 100U or the lower surface 100L of the redistribution structure interposer 100. As shown, the upper surface 100U may be at least partially defined by an upper surface of the redistribution insulating layer 110 and the lower surface 100L may be at least partially defined by a lower surface of the redistribution insulating layer 110.

The UBM structure 140 may be formed on (e.g., directly or indirectly on) the redistribution structure interposer 100. The UBM structure 140 may be at least partially located in an opening OP1 of the redistribution structure interposer 100 that may be at least partially defined by one or more inner surfaces 100IS of the redistribution structure interposer 100 (e.g., one or more inner surfaces of the redistribution insulating layer 110). The UBM structure 140 may be in contact with the uppermost redistribution line pattern 120 and/or the uppermost redistribution via pattern 130. In FIGS. 1 and 2, the UBM structure 140 is shown as being in contact with the redistribution line pattern 120, but the UBM structure 140 may be in contact with the redistribution via pattern 130. As will be described below, the UBM structure 140 and the connection member 150 may electrically connect the redistribution line pattern 120 and the redistribution via pattern 130 to the semiconductor chip 200.

The UBM structure 140 may include an adhesion layer 142, a seed layer 143, a lower UBM pad 144, and an upper UBM pad 146. The lower UBM pad 144 and the upper UBM pad 146 may be collectively referred to as a UBM pad 147. In some example embodiments, the lower UBM pad 144 and the upper UBM pad 146 may be separate portions of a single, unitary piece of material that defines the UBM pad 147, a boundary between the lower UBM pad 144 and the upper UBM pad 146 is defined by a location of discontinuous (e.g., step) change in the horizontal width of the UBM pad 147 between a first width W1 defining the lower UBM pad 144 and a second width W2 defining the upper UBM pad 146.

The adhesion layer 142 and the seed layer 143 may be disposed between the UBM pad 147 and the redistribution structure interposer 100 (e.g., the redistribution line pattern 120 and/or the redistribution via pattern 130). As shown, the adhesion layer 142 may be between the seed layer 143 and the redistribution structure interposer 100 (e.g., the redistribution line pattern 120 and/or the redistribution via pattern 130), and the seed layer 143 may be between the adhesion layer 142 and the UBM pad 147. The seed layer 143 may be disposed on the adhesion layer 142. The adhesion layer 142 and the seed layer 143 may be disposed on a lower portion of the UBM structure 140 and may be formed to conformally extend. Specifically, the adhesion layer 142 may be formed to conformally extend to a part of the upper surface 100U of the redistribution structure interposer 100, for example such that the adhesion layer 142 is directly on and contacts at least a portion of the upper surface 100U. In addition, the seed layer 143 may be formed to conformally extend to (e.g., to conformally cover and/or contact) at least a part of each of a lower surface 144L of the lower UBM pad 144, one or more side surfaces 144S of the lower UBM pad 144, and a lower surface 146L of the upper UBM pad 146. Accordingly, the adhesion layer 142 and the seed layer 143 may extend conformally on (e.g., directly underneath and/or directly horizontally adjacent to) a lower surface 144L of the lower UBM pad 144, one or more side surfaces 144S of the lower UBM pad 144, and a lower surface 146L of the upper UBM pad 146.

The adhesion layer 142 may strengthen the adhesion between the redistribution structure interposer 100 and the UBM pad 147. For example, the adhesion layer 142 may include metal including at least one of titanium (Ti), titanium tungsten (TiW), nickel vanadium (NiV), or chromium (Cr), or any alloy thereof. The seed layer 143 may act as a seed when forming the UBM pad 147. The seed layer 143 may provide a path through which current may flow when the UBM pad 147 is formed through an electroplating process, and the seed layer 143 may allow the UBM pad 147 to be formed on the seed layer 143. The seed layer 143 may include metal including at least one of copper (Cu), aluminum (Al), silver (Ag), tin (Sn), gold (Au), nickel (Ni), lead (Pb), or titanium (Ti), or any alloy thereof.

In some example embodiments of the inventive concepts, the seed layer 143 and the UBM pad 147 include different materials so that an interface is present therebetween, but, in some example embodiments, when the seed layer 143 and the UBM pad 147 include the same material, the seed layer 143 and the UBM pad 147 may be integrally formed because no interface is present therebetween, such that the seed layer 143 and the UBM pad 147 may be defined by separate portions of a single, unitary piece of material. In some example embodiments, one or both of the seed layer 143 and/or the adhesion layer 142 may be omitted from the semiconductor package 10.

The UBM pad 147 may include a lower UBM pad 144 disposed adjacent to and/or at least partially defining a lower portion of the UBM structure 140 and an upper UBM pad 146 disposed adjacent to and/or at least partially defining an upper portion of the UBM structure 140. An upper surface 146U of the upper UBM pad 146 may have a flat (e.g., planar or substantially planar) shape. In some example embodiments, the upper surface 146U of the upper UBM pad 146 may define an upper surface 146U of the UBM pad 147. In some example embodiments, the upper surface 146U of the upper UBM pad 146 and/or the upper surface 146U of the UBM pad 147 may define an upper surface 140U of the UBM structure 140.

The lower UBM pad 144 may be in contact with both the seed layer 143 and the upper UBM pad 146. In more detail, at least a part of each of lower and side surfaces 144L and 144S of the lower UBM pad 144 may be in contact with the seed layer 143. In addition, at least a part of the upper surface 144U of the lower UBM pad 144 may be in contact with the upper UBM pad 146.

The upper UBM pad 146 may be in contact with the lower UBM pad 144 and the connection member 150. In more detail, at least a part of a lower surface 146L of the upper UBM pad 146 may be in contact with the lower UBM pad 144 (e.g., in contact with the upper surface 144U of the lower UBM pad 144), and at least a part of each of the upper and side surfaces 146U and 146S of the upper UBM pad 146 may be in contact with the connection member 150.

The UBM pad 147 may have a T-shape. That is, a first width W1, which is a horizontal width of the lower UBM pad 144 in a horizontal direction (e.g., a direction parallel or substantially parallel to a main surface of the redistribution structure interposer 100, for example the upper surface 100U or the lower surface 100L thereof), may be less than a second width W2, which is a horizontal width of the upper UBM pad 146 in the horizontal direction. Accordingly, as shown, a horizontal width of the upper UBM pad 146 may be greater than a horizontal width of the lower UBM pad 144.

In the specification, the lower UBM pad 144 and the upper UBM pad 146 are merely formal divisions for explanation purpose, and the lower UBM pad 144 and the upper UBM pad 146 may be integrally formed as separate portions of a single, unitary piece of material, such that the upper surface 144U may be absent and there may not be any surfaces between the upper and lower UBM pads 146 and 144. As shown, the boundary between the lower and upper UBM pads 144 and 146, in example embodiments where the lower UBM pad 144 and the upper UBM pad 146 may be integrally formed as separate portions of a single, unitary piece of material, may be a location of a discontinuous (e.g., step) change in the width (e.g., horizontal width) of the UBM pad 147 between the first width W1 defining the lower UBM pad 144 and the second width W2 defining the upper UBM pad 146. In some example embodiments, the lower UBM pad 144 and upper UBM pad 146 may be formed separately.

In some example embodiments, a side surface 142S of the adhesion layer 142, a side surface 143S of the seed layer 143, and a side surface 147S of the UBM pad 147 which may be at least partially defined by a side surface 146S of the upper UBM pad 146) may at least partially define a side surface 140S of the UBM structure 140. The side surface 142S of the adhesion layer 142, the side surface 143S of the seed layer 143, and the side surface 147S of the UBM pad 147 (e.g., the side surface 146S of the upper UBM pad 146) may be aligned in the vertical direction (Z direction), as shown for example in at least FIG. 2, for example such that the side surface 142S, the side surface 143S, and the side surface 147S (146S) are coplanar with each other. As a result, a side surface 142S of the adhesion layer 142, a side surface 143S of the seed layer 143, and a side surface 147S of the UBM pad 147 (e.g., a side surface 146S of the upper UBM pad 146) may define a side surface 140S of the UBM structure 140 that extends continuously in the vertical direction (Z direction) without discontinuous (e.g., step) changes of position in a horizontal direction (e.g., X and/or Y directions) and/or without any offset of the side surface 140S in the horizontal direction. For example the side surface 140S may be a planar surface or a surface extending linearly in the vertical direction (Z direction). In some example embodiments, the UBM pad 147 may include multiple side surfaces 147S that are aligned in the vertical direction with separate, respective side surfaces 142S of the adhesion layer 142 and separate, respective side surfaces 143S of the seed layer 143 to define separate, respective side surfaces 140S.

In addition, the connection member 150 may be disposed on the UBM structure 140. The connection member 150 may be a solder bump. The UBM structure 140 and the connection member 150 may electrically connect the redistribution structure interposer 100 (e.g., the redistribution line pattern 120 and the redistribution via pattern 130) to the semiconductor chip 200.

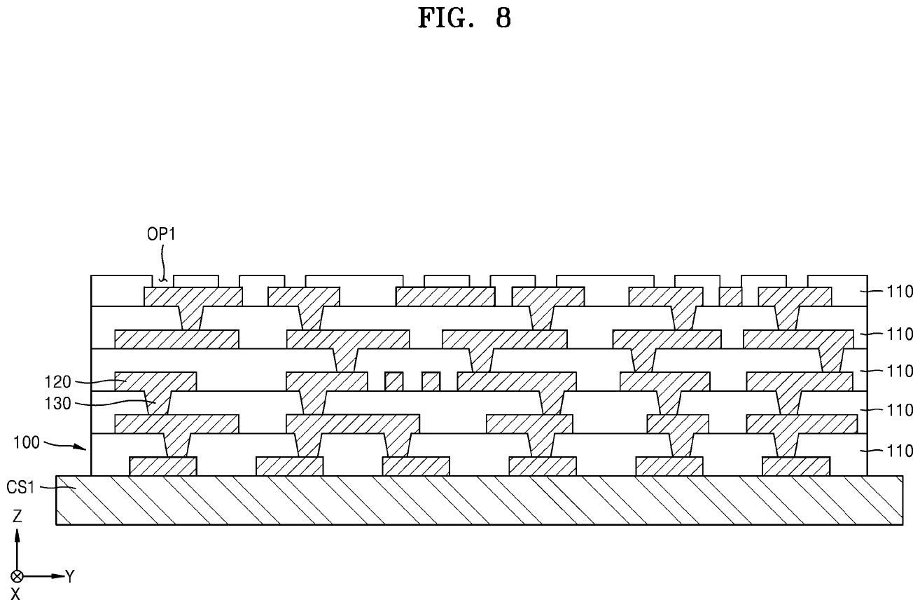

The connection member 150 may be in contact with each of the redistribution structure interposer 100, the UBM structure 140, and a chip pad 240 of the semiconductor chip 200. In more detail, the connection member 150 may be in contact with at least a part of each of an upper surface 110U of the uppermost redistribution insulating layer 110 (which may at least partially define an upper surface 100U of the redistribution structure interposer 100), at least one side surface 142S of the adhesion layer 142, at least one side surface 143S of the seed layer 143, and at least one side surface 147S of the UBM pad 147 (which may be at least partially defined by at least one side surface 146S of the upper UBM pad 146). Accordingly, the connection member 150 may be in contact (e.g., direct contact) with one or more side surfaces 147S of the UBM pad 147 and may be further in contact (e.g., direct contact) with the redistribution structure interposer 100 (e.g., in contact with an upper surface 100U of the redistribution structure interposer 100 which may be at least partially defined by the upper surface 110U of a redistribution insulating layer 110). The reason why the connection member 150 has such a shape will be explained in more detail with reference to FIGS. 8 to 15 illustrating a method of manufacturing the semiconductor package 10.

The connection member 150 is formed in contact with at least a part of one or more side surfaces 140S of the UBM structure 140 (which may be at least partially defined by one or more side surfaces 142S of the adhesion layer 142, one or more side surfaces 143S of the seed layer 143, and/or one or more side surfaces 147S of the UBM pad 147), and thus, electrical connectivity between the connection member 150 and the UBM structure 140 may be increased. Accordingly, a contact area between the UBM structure 140 and the connection member 150 increases and wetting is enhanced based on the connection member 150 being in contact with at least a part of one or more side surfaces 140S of the UBM structure 140, which may include the connection member 150 being in contact with one or more side surfaces 147S of the UBM pad 147 and may further include the connection member 150 being in contact with one or more side surfaces 142S of the adhesion layer 142, one or more side surfaces 143S of the seed layer 143, or any combination thereof. Thus, the semiconductor package 10 may implement a fine bump and/or fine pad pitch without compromising electrical characteristics of the semiconductor package 10. Accordingly, the semiconductor package 10 may have a reduced size due to exhibit a smaller (e.g., finer) pitch between adjacent chip pads 240 of a same semiconductor chip and/or adjacent chip pads 240 of separate semiconductor chips 200, a smaller (e.g., finer) pitch between UBM pads 147 on the redistribution structure interposer 100, and/or a smaller (e.g., finer) pitch between adjacent connection members 150 on the redistribution structure interposer 100, without compromising electrical characteristics (e.g., electrical connectivity and/or electrical reliability) of the semiconductor package 10, for example without compromising contact area of the electrical connection between the semiconductor chips 200 and the redistribution structure interposer 100 through respective UBM pads 147 and connection members 150, and thus without compromising electrical connections between the semiconductor chips 200 and the redistribution structure interposer 100 through respective UBM pads 147 and connection members 150 (e.g., without comprising electrical connectivity between the UBM pads 147 and respective connection members 150).

A plurality of external connection terminals 160 may be disposed on the lower surface 100L of the redistribution structure interposer 100. Each external connection terminal 160 may be disposed on a separate pad 162. Each pad 162 may be at least partially defined by one or more redistribution line patterns 120 and/or one or more redistribution via patterns 130. Each pad 162 may comprise a same or substantially same material as the redistribution line pattern 120 and/or the redistribution via pattern 130, but example embodiments are not limited thereto. Each pad 162 may include metal including copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or any alloy thereof, but are not limited thereto. The external connection terminal 160 may transmit an electrical signal of the semiconductor chip 200 to the outside of the semiconductor package 10. In some example embodiments, the external connection terminal 160 may transmit the electrical signal of the outside of the semiconductor package 10 to the semiconductor chip 200. Through the external connection terminal 160, the semiconductor package 10 may be electrically connected to a main board (e.g., a printed circuit board (PCB)) of an electronic device on which the semiconductor package 10 is mounted. The external connection terminal 160 may include a solder bump and/or a solder ball. The redistribution structure interposer 100 may be electrically connected to the external connection terminal 160 through the lowermost redistribution line pattern 120.

Although not shown in FIG. 1, a pad in direct contact with the external connection terminal 160 may also have a shape similar to that of the UBM structure 140.

The semiconductor chip 200 may be disposed on (e.g., directly or indirectly on) the connection member 150. The semiconductor chip 200 may include a semiconductor substrate 220 and a chip pad 240. The semiconductor chip 200 may be a logic chip or a memory chip. The logic chip may be, for example, a microprocessor, analog device, or digital signal processor. In addition, the memory chip may be a volatile memory chip such as Dynamic Random Access Memory (DRAM) or Static Random Access Memory (SRAM), or may be a non-volatile memory chip such as Phase-change Random Access Memory (PRAM), Magnetoresistive Random Access Memory (MRAM), Resistive Random Access Memory (RRAM), or Ferroelectric Random Access Memory (FeRAM). In some example embodiments, the semiconductor chip 200 may be a high bandwidth memory chip. The semiconductor package 10 may include a plurality of semiconductor chips 200.

The semiconductor chip 200 may be understood as a concept including a semiconductor device including an integrated circuit. Specifically, the semiconductor chip 200 may include the semiconductor substrate 220 including an active surface and an inactive surface which face each other. A circuit unit implementing an integrated circuit function of the semiconductor chip 200 may be formed on the active surface of the semiconductor substrate 220 through a semiconductor manufacturing process. That is, on the semiconductor substrate 220, wiring layers such as a conductive wiring, interlayer insulating layers disposed between the wiring layers, and individual unit devices may be formed.

The semiconductor chip 200 may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

In addition, the semiconductor chip 200 may include the chip pad 240 formed on the semiconductor substrate 220 and expanding the function of the circuit unit to the outside. The chip pad 240 may have a peripheral portion covered by and a central portion opened by the protective layer formed on the active surface of the semiconductor substrate 220. The protective layer may physically and chemically protect the semiconductor device on the active side of the semiconductor substrate 220. The protective layer may include, for example, an inorganic insulating material such as silicon oxide, silicon nitride, or silicon oxynitride, an organic insulating material such as an insulating polymer, or an insulating material including a combination thereof.

For example, the chip pad 240 may have a polygonal shape such as a square, hexagon, or octagon, or a circular or oval shape. The chip pad 240 may have a certain size or more to withstand electrical and mechanical stress. The connection member 150 may be disposed on a lower portion of the chip pad 240.

In the specification, a lower surface of a component of the semiconductor package 10, excluding the external connection terminal 160, may be defined as a surface adjacent to the external connection terminal 160 among two surfaces of the component spaced apart in the vertical direction (Z direction), and a surface opposite to a lower surface of the component may be defined as the upper surface of the component. In addition, a surface in contact between the redistribution structure interposer 100 and the external connection terminal 160 may be defined as the upper surface of the external connection terminal 160, and a surface opposite to the upper surface of the external connection terminal 160 may be defined as the lower surface of the external connection terminal 160.

The molding layer 300 covering at least a part of each of the UBM structure 140, the connection member 150, and the semiconductor chip 200 (e.g., covering at least one or more side surfaces of the semiconductor chip 200) may be formed on the redistribution structure interposer 100. The molding layer 300 may protect the semiconductor chip 200 from external influences such as contamination and/or shock. For example, the molding layer 300 may include epoxy mold compound, resin, etc. In addition, the molding layer 300 may be formed by processes such as compression molding, lamination, and screen printing. In some example embodiments, the molding layer 300 may cover only the one or more side surfaces of the semiconductor chip 200 so that the upper surface of the semiconductor chip 200 is exposed to the outside (e.g., exposed from the molding layer 300). The molding layer 300 may configure the appearance of the semiconductor package 10, and the redistribution structure interposer 100 may be expanded and disposed by using the molding layer 300.

In a general semiconductor package, a connection member is in contact with only an upper surface of a UBM structure and does not contact side surfaces of the UBM structure. Therefore, the electrical connectivity between the UBM structure and the connection member is relatively low, causing a problem in which the electrical reliability of a semiconductor package is relatively low.

In some example embodiments of the inventive concepts, in the semiconductor package 10, the connection member 150 is in contact with at least a part of each of the upper surface 140U of the UBM structure 140 and one or more (or all) side surfaces 140S of the UBM structure 140 (e.g., where the upper surface 140U may be at least partially defined by an upper surface 147U of the UBM pad 147 which may be further at least partially defined by an upper surface 146U of the upper UBM pad 146, and where each side surface 140S of the UBM structure 140 may be at least partially defined by at least a side surface 147S of the UBM pad 147 which may be further at least partially defined by a side surface 146S of the upper UBM pad 146, although example embodiments are not limited thereto), and thus, the electrical connectivity between the UBM structure 140 and the connection member 150 may be relatively higher than semiconductor packages where the connection member is in contact with only an upper surface of a UBM structure and does not contact any side surfaces of the UBM structure. Accordingly, the wetting of the connection member 150 is improved, and thus, the electrical reliability of the semiconductor package 10 (e.g., a reliability of electrical connections between the semiconductor chip 200 and the redistribution structure interposer 100 based on the contact area of the electrical connections) may be improved.

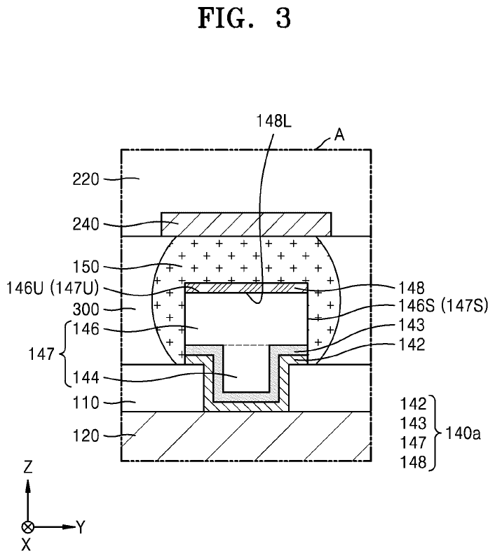

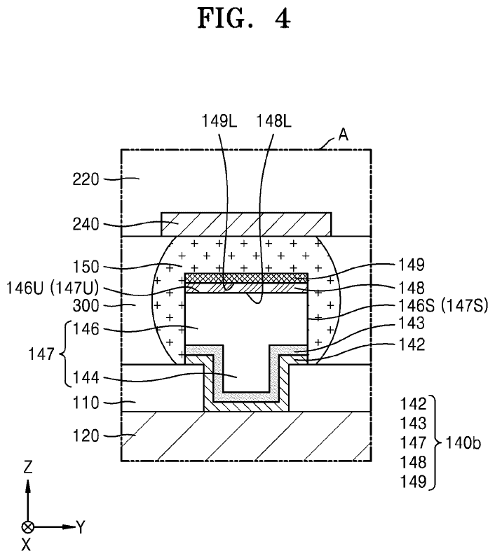

FIGS. 3 and 4 are enlarged cross-sectional views of area A of FIG. 1 according to some example embodiments. The example embodiments shown in FIGS. 3 and 4 are described with reference to FIGS. 1 and 2 together.

Referring to FIGS. 3 and 4, a UBM structure 140a of FIG. 3 may include the adhesion layer 142, the seed layer 143, the lower UBM pad 144, the upper UBM pad 146, and a first additional plating layer 148 (also referred to herein interchangeably as a plating layer or an additional plating layer). In addition, a UBM structure 140b of FIG. 4 may include the adhesion layer 142, the seed layer 143, the lower UBM pad 144, the upper UBM pad 146, the first additional plating layer 148, and a second additional plating layer 149 (also referred to herein interchangeably as a plating layer or an additional plating layer, particularly in example embodiments where the first additional plating layer 148 is referred to as a plating layer). The adhesion layer 142, the seed layer 143, the lower UBM pad 144, and the upper UBM pad 146 of FIGS. 3 and 4 are the same or substantially the same as the adhesion layer 142, the seed layer 143, the lower UBM pad 144, and the upper UBM pad 146 of the UBM structure 140 of FIGS. 1 and 2, respectively, and thus, herein, the first additional plating layer 148 and the second additional plating layer 149 are mainly described.

The first additional plating layer 148 and/or the second additional plating layer 149 may function as a barrier layer. The first additional plating layer 148 and/or the second additional plating layer 149 may be disposed between the UBM pad 147 (e.g., the upper UBM pad 146) and the connection member 150, for example between the UBM pad 147 and the connection member 150 in the vertical direction (Z direction). The first additional plating layer 148 and/or the second additional plating layer 149 may be disposed between the upper UBM pad 146 and the connection member 150 (e.g., in the vertical direction). The first additional plating layer 148 and the second additional plating layer 149 may be sequentially stacked on the upper UBM pad 146 (e.g., in the vertical direction).

The first additional plating layer 148 and the second additional plating layer 149 may each independently include a conductive material including copper (Cu), aluminum (Al), silver (Ag), tin (Sn), gold (Au), nickel (Ni), lead (Pb), titanium (Ti), or any alloy thereof. The first additional plating layer 148 and the second additional plating layer 149 may include different materials. In some example embodiments, the first additional plating layer 148 and the second additional plating layer 149 may include the same material or substantially the same material.

The first additional plating layer 148 and/or the second additional plating layer 149 may be disposed between the UBM pad 147 and the connection member 150, and thus, the connection member 150 may be in contact with one or more side surfaces 147S of the UBM pad 147 and spaced apart from an upper surface 147U of the UBM pad 147. That is, the UBM pad 147 may be in contact with a lower surface 148L of the first additional plating layer 148 and/or a lower surface 149L of the second additional plating layer 149.

In FIGS. 3 and 4, one and two plating layers are shown to be disposed between the UBM pad 147 and the connection member 150, respectively, but the inventive concepts is not limited thereto. For example, three or more plating layers may be disposed between the UBM pad 147 and the connection member 150.

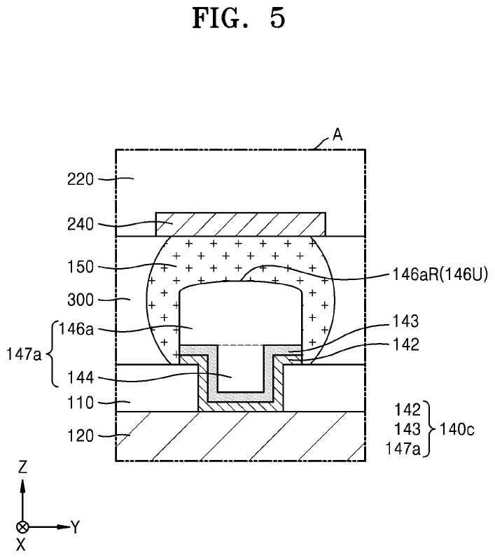

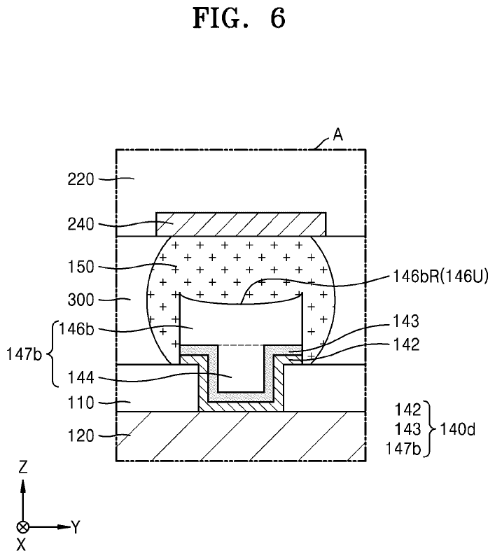

FIGS. 5 and 6 are enlarged cross-sectional views of area A of FIG. 1 according to some example embodiments. The example embodiments shown in FIGS. 5 and 6 are described with reference to FIGS. 1 and 2 together.

Referring to FIGS. 5 and 6, a UBM structure 140c of FIG. 5 may include the adhesion layer 142, the seed layer 143, the lower UBM pad 144, and an upper UBM pad 146a, where the lower UBM pad 144 and the upper UBM pad 146a collectively define a UBM pad 147a. In some example embodiments, a UBM structure 140d of FIG. 6 may include the adhesion layer 142, the seed layer 143, the lower UBM pad 144, and an upper UBM pad 146b, where the lower UBM pad 144 and the upper UBM pad 146b collectively define a UBM pad 147b. The adhesion layer 142, the seed layer 143, and the lower UBM pad 144 of FIGS. 5 and 6 are the same or substantially the same as the adhesion layer 142, the seed layer 143, and the lower UBM pad 144 of the semiconductor package 10 of FIGS. 1 and 2, respectively, and thus, herein, the upper UBM pads 146a and 146b are mainly described.

An upper surface 146U of the upper UBM pad 146a of FIG. 5 may have an upwardly convex shape, and an upper surface 146U of the upper UBM pad 146b of FIG. 6 may have a downwardly convex shape. That is, the upper surface of the upper UBM pad 146a of FIG. 5 may include an upper surface 146U that includes a convexly rounded curved surface 146aR, and the upper surface of the upper UBM pad 146b of FIG. 6 may include an upper surface 146U that includes a concavely rounded curved surface 146bR. This may be a feature resulting from a process of forming each of the upper UBM pads 146a and 146b.

The shapes of the upper UBM pads 146a and 146b are not limited thereto and may be modified in various ways. For example, the upper surfaces 146U of the upper UBM pads 146a and 146b may each have a concave-convex shape. That is, at least a part of the upper surfaces 146U of the upper UBM pads 146a and 146b may not be a flat shape.

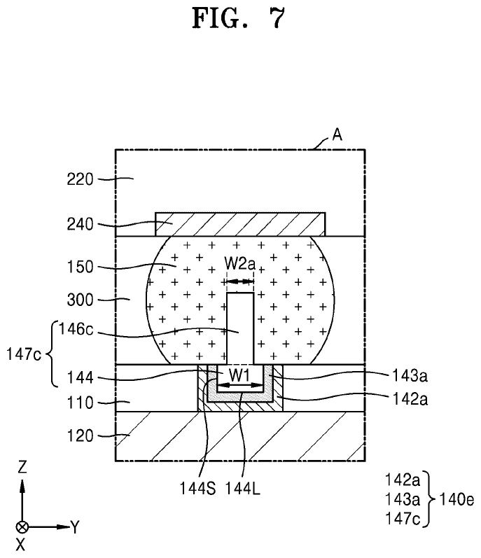

FIG. 7 is an enlarged cross-sectional view of area A of FIG. 1 according to some example embodiments. The example embodiments shown in FIG. 7 are described with reference to FIGS. 1 and 2 together.

Referring to FIG. 7, a UBM structure 140e may include an adhesion layer 142a, a seed layer 143a, the lower UBM pad 144, and an upper UBM pad 146c, where the lower UBM pad 144 and the upper UBM pad 146c collectively define a UBM pad 147c. The first width W1, which is the horizontal width of the lower UBM pad 144, may be greater than a second width W2a, which is a horizontal width of the upper UBM pad 146c. In some example embodiments, the first width W1, which is the horizontal width of the lower UBM pad 144, may be equal to the second width W2a, which is the horizontal width of the upper UBM pad 146c.

When the first width W1 is equal to the second width W2a and/or the first width W1 is greater than the second width W2a, the adhesion layer 142a and the seed layer 143a may be spaced apart from the upper UBM pad 146c. That is, the adhesion layer 142a may not be in contact with the upper UBM pad 146c. The adhesion layer 142a may be in contact with at least a part of each of lower and side surfaces 144L and 144S of the lower UBM pad 144. In addition, the connection member 150 may be in contact with the redistribution structure interposer 100, the UBM structure 140e, and the molding layer 300. In more detail, the connection member 150 may be in contact with the redistribution structure interposer 100 (e.g., the redistribution insulating layer 110), the adhesion layer 142a, the lower UBM pad 144, and/or the upper UBM pad 146c.

FIGS. 8, 9, 10, 11, 12, 13, 14, and 15 are cross-sectional views illustrating a method of manufacturing a semiconductor package according to some example embodiments. The method of FIGS. 8 to 15 is described with reference to FIGS. 1 to 7.

Referring to FIG. 8, the redistribution structure interposer 100 (e.g., a redistribution structure interposer 100 including the redistribution insulating layer 110, the redistribution line pattern 120, and the redistribution via pattern 130) may be formed on a first carrier substrate CS1.

The first carrier substrate CS1 may support the redistribution structure interposer 100 and may include a material having stability with respect to a semiconductor process. For example, the first carrier substrate CS1 may include glass or aluminum oxide. In some example embodiments, to enable the first carrier substrate CS1 to stably support the redistribution structure interposer 100, a first adhesion film (not shown) may be disposed between the first carrier substrate CS1 and the redistribution structure interposer 100.

The redistribution line pattern 120 and the redistribution via pattern 130 may be formed by forming the redistribution insulating layer 110 including a photosensitive insulating material on the first carrier substrate CS1, and performing an exposure process and a development process on the photosensitive insulating material. After at least a part of the redistribution insulating layer 110 may be removed through an etching process, the redistribution line pattern 120 and the redistribution via pattern 130 may be formed through a plating process. The redistribution line pattern 120 may extend in the horizontal direction (X direction and/or Y direction) inside the redistribution insulating layer 110, and the redistribution via pattern 130 may extend in the vertical direction (Z direction) inside the redistribution insulating layer 110. The redistribution line pattern 120 and the redistribution via pattern 130 may be formed by stacking metal and/or metal alloy on a seed layer.

For example, the redistribution insulating layer 110 may include an insulating material, such as PID resin, and may further include photosensitive polyimide and/or inorganic filler, but is not limited thereto. The redistribution line pattern 120 and the redistribution via pattern 130 may each independently include metal including copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or any alloy thereof, but are not limited thereto.

By repeating this process multiple times, the redistribution structure interposer 100 (e.g., a redistribution structure interposer 100) may be formed. Thereafter, a plurality of first openings OP1 may be formed by removing at least a part of the upper portion of the redistribution structure interposer 100. Each of the plurality of first openings OP1 may expose at least a part of an upper surface of the uppermost redistribution line pattern 120 and/or the uppermost redistribution via pattern 130 to the outside. In FIG. 8, a part of the upper surface of the redistribution line pattern 120 is shown as being exposed by the first opening OP1, but a part of the upper surface of the redistribution via pattern 130 may be exposed by the first opening OP1.

In addition, in FIG. 8, the upper surface of the redistribution line pattern 120 is shown to be exposed by removing at least a part of an upper portion of the redistribution insulating layer 110, but the upper surface of the redistribution line pattern 120 may be exposed by adding a protective layer (not shown) on the redistribution insulating layer 110 and then, removing at least a part of the protective layer. In this case, the protective layer may include an inorganic insulating material, an organic insulating material, or an insulating material including a combination thereof.

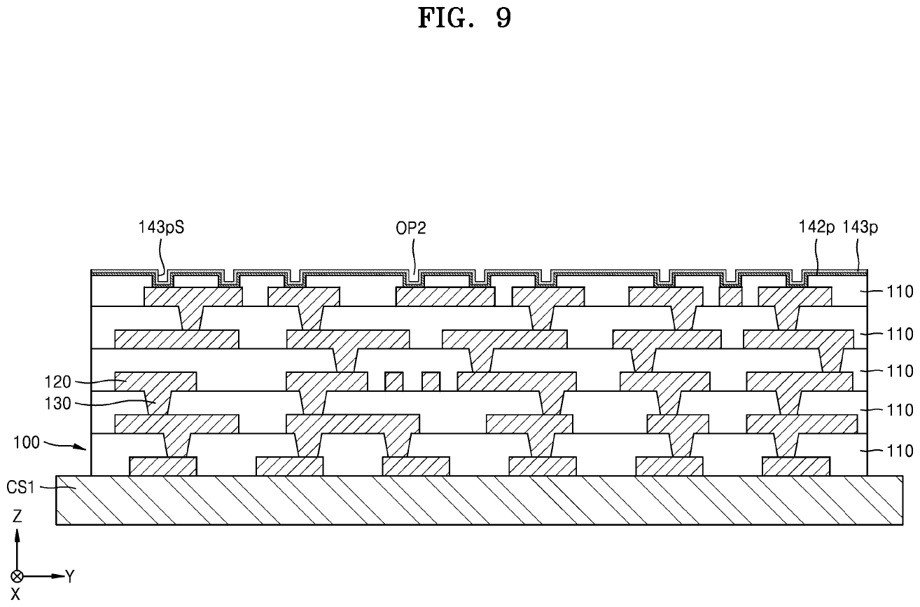

Referring to FIG. 9, a preliminary adhesion layer 142p and a preliminary seed layer 143p are formed on a resultant of FIG. 8 (e.g., formed on the redistribution structure interposer 100). The preliminary adhesion layer 142p and the preliminary seed layer 143p may be conformally formed on the resultant of FIG. 8. At least a part of each of the preliminary adhesion layer 142p and the preliminary seed layer 143p may be disposed inside the first opening OP1 of FIG. 8. The preliminary adhesion layer 142p may include metal including at least one of titanium (Ti), titanium tungsten (TiW), nickel vanadium (NiV), or chromium (Cr), or any alloy thereof. The preliminary seed layer 143p may include metal including at least one of copper (Cu), aluminum (Al), silver (Ag), tin (Sn), gold (Au), nickel (Ni), lead (Pb), or titanium (Ti) or any alloy thereof.

The preliminary adhesion layer 142p may increase an adhesion force between the redistribution structure interposer 100 and the UBM pad 147. The preliminary seed layer 143p may be a seed for forming the UBM pad 147 (e.g., for forming the lower UBM pad 144 and the upper UBM pad 146). For example, when the lower UBM pad 144 and the upper UBM pad 146 are formed through an electroplating process, the preliminary seed layer 143p may provide a path through which current may flow so that the lower UBM pad 144 and the upper UBM pad 146 may be formed on an upper portion of the preliminary seed layer 143p.

The preliminary adhesion layer 142p and the preliminary seed layer 143p may be disposed at least partially inside the first opening OP1 of FIG. 8 to form a second opening OP2. As shown, the second opening OP2 may be at least partially defined by one or more inner surfaces 143pS of the preliminary seed layer 143p. In a subsequent process, the lower UBM pad 144 may be formed in the second opening OP2.

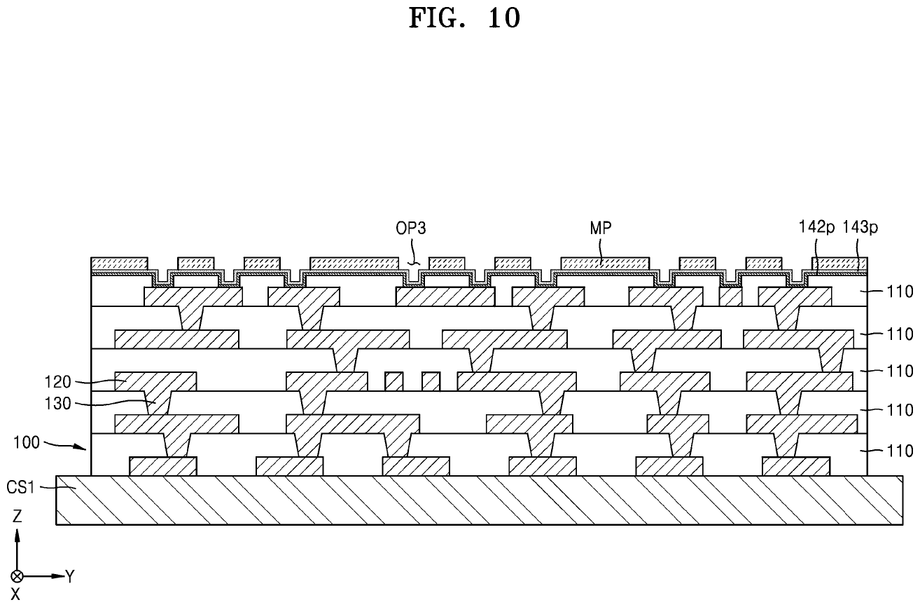

Referring to FIG. 10, a mask pattern MP is formed on the preliminary seed layer 143p. The mask pattern MP may expose at least a part of the preliminary seed layer 143p. The part of the preliminary seed layer 143p exposed by the mask pattern MP may correspond to a part where the UBM pad 147 is formed in the subsequent process. As the mask pattern MP is formed, a third opening OP3 may be formed. In a subsequent process, the UBM pad 147 may be formed inside the second opening OP3.

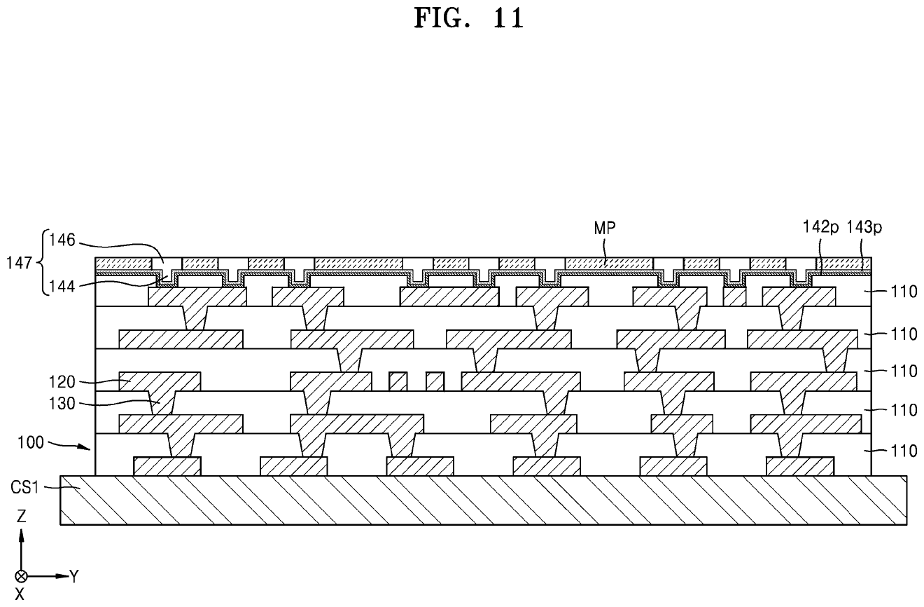

Referring to FIG. 11, the UBM pad 147 may be formed inside the third opening OP3 of FIG. 10. The UBM pad 147 may be formed on the preliminary seed layer 143p. The UBM pad 147 may include the lower UBM pad 144 and the upper UBM pad 146. The UBM pad 147 may have a T shape in which a horizontal width of the upper UBM pad 146 is greater than a horizontal width of the lower UBM pad 144. As shown, the lower UBM pad 144 may be defined by a portion of the UBM pad 147 formed in the second opening OP2, where the lower UBM pad 144 may have dimensions defined by the dimensions of the second opening OP2.

To form the UBM pad 147, electroplating may be performed. For example, the UBM pad 147 may include a conductive material such as copper (Cu), aluminum (Al), silver (Ag), tin (Sn), gold (Au), nickel (Ni), lead (Pb), titanium (Ti), or any alloy thereof. The UBM pad 147 may be formed to at least partially fill an area defined by the mask pattern MP without completely filling the area. That is, a height of the UBM pad 147 (e.g., a height of an upper surface 147U of the UBM pad 147 above the main surface of the redistribution structure interposer 100, for example the upper surface 100U, in the vertical direction) may be formed to be lower than a height of the mask pattern MP (e.g., a height of an upper surface of the mask pattern MP above the main surface of the redistribution structure interposer 100, for example the upper surface 100U, in the vertical direction).

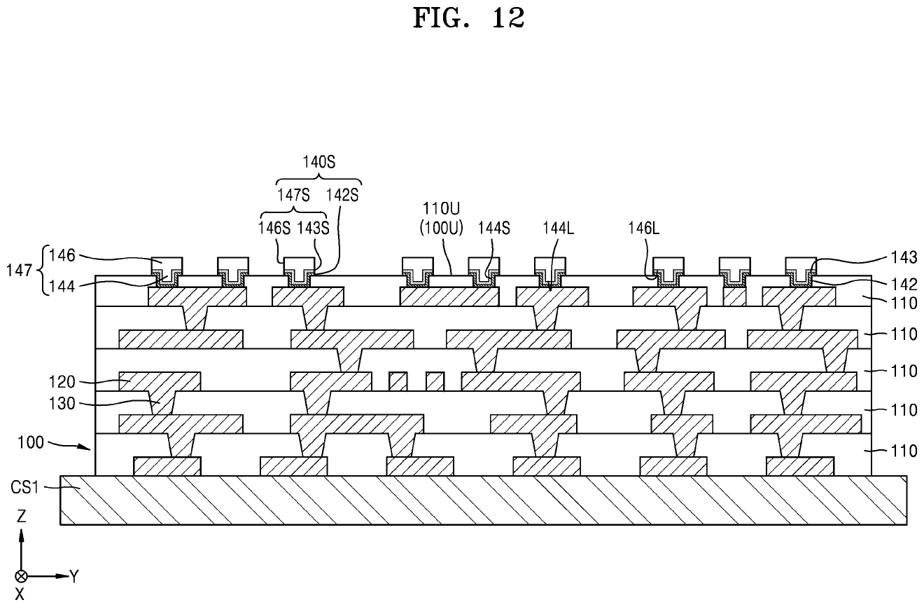

Referring to FIG. 12, the mask pattern MP of FIG. 11 may be removed by performing ashing and stripping processes. In addition, the adhesion layer 142 and the seed layer 143 may be formed by removing at least a part of each of the preliminary adhesion layer 142p of FIG. 11 and the preliminary seed layer 143p of FIG. 11 by dry etching and/or wet etching. Side surfaces 146S of the upper UBM pad 146 may be aligned (e.g., overlapped, extending coplanar or substantially coplanar, etc.) in the vertical direction (Z direction) with side surfaces 142S and 143S of each of the adhesion layer 142 and the seed layer 143, such that the side surfaces 146S, 143S, and 142S may collectively define a side surface 140S extending continuously in the vertical direction (e.g., Z direction) without any discontinuous (e.g., step) changes of position in a horizontal direction and/or without any or substantially any offset in a horizontal direction.

The adhesion layer 142 and the seed layer 143 may be disposed between the redistribution structure interposer 100 and the UBM pad 147. The adhesion layer 142 may be in contact with the redistribution structure interposer 100, for example in contact with at least a part of each of the redistribution insulating layer 110 and the redistribution line pattern 120 (e.g., an upper surface 110U of the redistribution insulating layer 110 as shown in FIG. 2). The seed layer 143 may be in contact with at least a part of the lower surface 144L of the lower UBM pad 144, one or more or all side surfaces 144S of the lower UBM pad 144, and the lower surface 146L of the upper UBM pad 146.

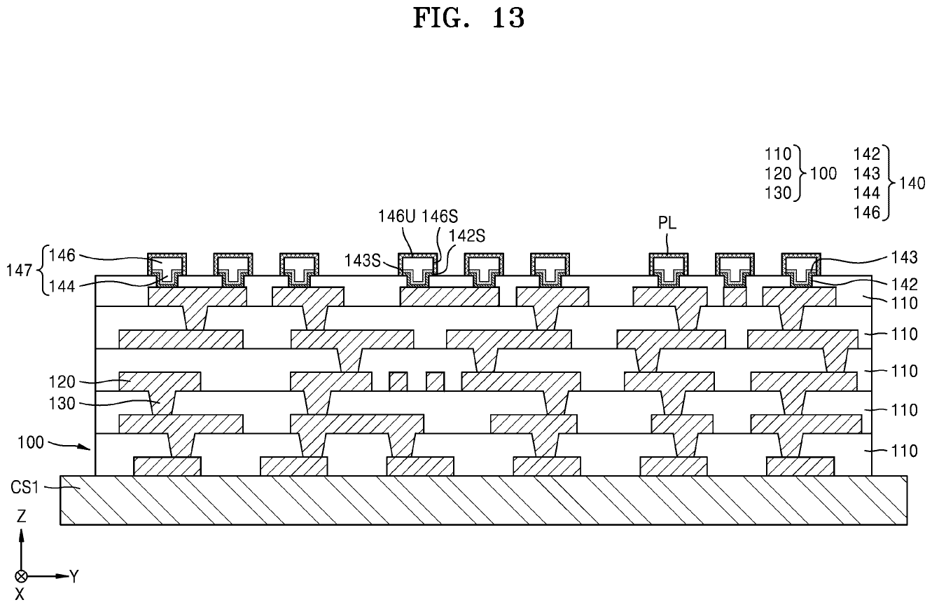

Referring to FIG. 13, a plating layer PL covering at least a part of each of the upper surface 146U and one or more side surfaces 146S of the upper UBM pad 146 is formed. As shown, the plating layer PL may be in contact with one or more side surfaces 147S of the UBM pad 147, which may include being in contact with one or more side surfaces 146S of the upper UBM pad 146. As further shown, the plating layer PL may be in contact with one or more side surfaces 142S of the adhesion layer 142, one or more side surfaces 143S of the seed layer 143, one or more side surfaces 146S of the upper UBM pad 146 (one or more side surfaces 147S of the UBM pad 147), or any combination thereof. As shown, the plating layer PL may be in contact with the redistribution structure interposer 100, including for example being in contact with the upper surface 100U of the redistribution structure interposer 100. In order for the plating layer PL to cover one or more side surfaces 142S of the adhesion layer 142, one or more side surfaces 143S of the seed layer 143, and one or more side surfaces 146S of the upper UBM pad 146 (e.g., one or more side surfaces 147S of the UBM pad 147), the plating layer PL may be formed after the mask pattern MP is removed (e.g., subsequently to removing the mask pattern MP).

The plating layer PL may include a conductive material including at least one of copper (Cu), aluminum (Al), silver (Ag), tin (Sn), gold (Au), nickel (Ni), lead (Pb), titanium (Ti), or any alloy thereof. The plating layer PL may be formed using an electroless plating method. For example, the forming of the plating layer PL may be performed based on performing an electroless plating method. For example, the plating layer PL may be formed using (e.g., based on performing) an immersion plating method. For example, the forming of the plating layer PL may be performed based on performing an immersion plating method. When the plating layer PL is formed using an electroless plating method, a thickness of the plating layer PL may be reduced, and a manufacturing process may be simplified, and thus, the plating layer PL may be more efficiently formed. In addition, when the plating layer PL is formed using an electroless plating method, electrical noise may be reduced and process reliability may be increased, thereby reducing the likelihood of process defects in the semiconductor package 10 and thus increasing the reliability of the manufactured semiconductor package 10 and any electronic device including same.

Although not shown in the drawing, surface treatment may be performed on the upper UBM pad 146 before the plating layer PL is formed.

Although not shown in FIG. 13, when the first additional plating layer 148 and/or the second additional plating layer 149 is disposed between the upper surface 146U of the upper UBM pad 146 (which may define the upper surface 147U of the UBM pad 147) and the plating layer PL, the UBM pad 147 of FIG. 3 or FIG. 4 may be formed.

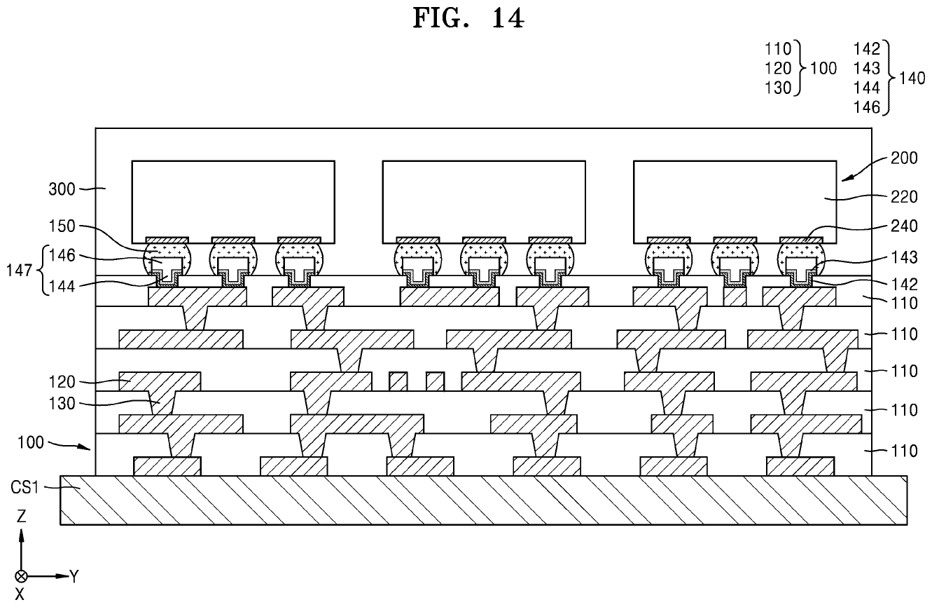

Referring to FIG. 14, the semiconductor chip 200 is mounted on a resultant of FIG. 13, and the molding layer 300 is formed on the redistribution structure interposer 100.

First, the connection member 150 may be mounted on the UBM pad 147. The connection member 150 in contact with the semiconductor chip 200 may be attached onto the plating layer PL through a reflow process. As described above, the plating layer PL is formed on the upper surface 146U and one or more (or all) side surfaces 146S of the upper UBM pad 146, and thus, the connection member 150 may also be in contact with the upper surface 146U and one or more (or all) side surfaces 146S of the upper UBM pad 146. In addition, the connection member 150 may be in contact with the upper surface 100U of the redistribution structure interposer 100 (e.g., the upper surface 110U of the redistribution insulating layer 110), the adhesion layer 142 (e.g., one or more side surfaces 142S thereof), and the seed layer 143 (e.g., one or more side surfaces 143S thereof). Accordingly, a contact surface between the connection member 150 and the UBM pad 147 increases in relation to semiconductor packages where the connection member 150 only contacts the upper surface 147U of the UBM pad 147 without contacting side surfaces of the UBM structure 140), and thus, the electrical characteristics of the semiconductor package 10 may be improved based on the connection member 150 being in contact with one or more side surfaces 147S of the UBM pad and further in contact with the redistribution structure interposer 100.

In a process of attaching the connection member 150 onto the UBM pad 147, the plating layer PL may diffuse into the connection member 150. Accordingly, the UBM pad 147 and the connection member 150 may be in contact (e.g., direct contact) with each other, and the connection member 150 may include the material of the plating layer PL. For example, when the plating layer PL includes gold (Au), the connection member 150 may also include gold (Au).

The semiconductor chip 200 may be an individualized semiconductor die, or may be a sub-package in which the semiconductor die is molded. The semiconductor chip 200 is mounted so that the active surface on which the chip pad 240 is formed faces downward, so that the chip pad 240 of the semiconductor chip 200 may be aligned with the upper surface of the UBM pad 147.

A plurality of semiconductor chips 200 may be mounted. Some of the plurality of semiconductor chips 200 may be logic chips, and the others may be memory chips.

In a process of electrically connecting the connection member 150 to the semiconductor chip 200, a gap may be formed between the connection member 150 and the semiconductor chip 200. Because the gap may cause a problem in the reliability of a connection between the connection member 150 and the semiconductor chip 200, an underfill (not shown) may be injected and hardened to reinforce the connection.

By the underfill, the semiconductor chip 200 is more stably fixed on the connection member 150, and despite a difference in thermal expansion coefficient between the connection member 150 and the semiconductor chip 200, the connection member 150 and the semiconductor chip 200 are not electrically separated. In some example embodiments, the molding layer 300 may be directly filled into the gap between the connection member 150 and the semiconductor chip 200, and in this case, the underfill may not be necessary.

The molding layer 300 may be formed on the redistribution structure interposer 100. Forming the molding layer 300 on the redistribution structure interposer 100 may include at least partially forming the molding layer to cover (e.g., contact) one or more side surfaces of the semiconductor chip 200. The molding layer 300 may be formed on the redistribution structure interposer 100 such that the molding layer 300 may cover the side and upper surfaces of the semiconductor chip 200 on the redistribution structure interposer 100. In some example embodiments, the molding layer 300 may cover only the side surfaces of the semiconductor chip 200 so that the upper surface of the semiconductor chip 200 is exposed to the outside (e.g., exposed from the molding layer 300). The molding layer 300 may serve to protect the semiconductor chip 200 from external influences such as shock. For example, the molding layer 300 may include epoxy mold compound, resin, etc.

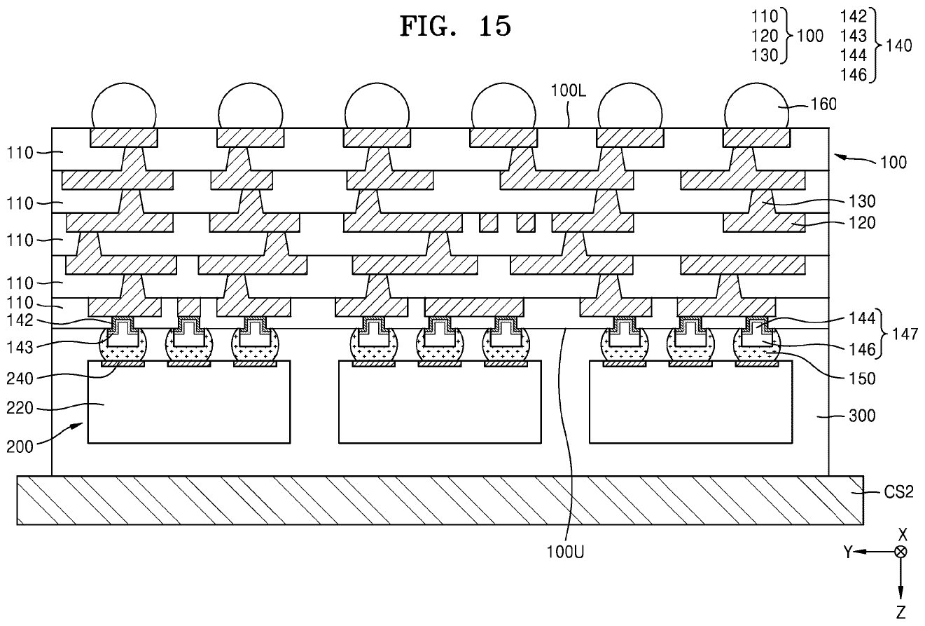

Referring to FIG. 15, a second carrier substrate CS2 may be attached onto the molding layer 300 to face the first carrier substrate CS1, and the first carrier substrate CS1 of FIG. 14 may be removed.

The second carrier substrate CS2 may be the same or substantially the same as the first carrier substrate CS1 in FIG. 14. In order to facilitate attachment of the second carrier substrate CS2, a second adhesion film (not shown) may be formed between the second carrier substrate CS2 and the molding layer 300. The adhesion film may be in a liquid form or a gel form that may be easily deformed at a certain pressure.

Thereafter, after turning over a resultant, the external connection terminal 160 may be formed on the lower surface 100L of the redistribution structure interposer 100. The external connection terminal 160 may be formed through a reflow process. The external connection terminal 160 may be formed on the lower surface 100L of the redistribution structure interposer 100 so that the semiconductor package 10 of FIG. 1 may be formed.

In a general semiconductor package manufacturing method, a plating layer is disposed on an upper surface of a UBM pad, and side surfaces of the UBM pad are not in contact with a connection member.

In the method of manufacturing the semiconductor package according to some example embodiments of the inventive concepts, the plating layer PL may be in contact with one or more (or all) side surfaces 147S of the UBM pad 147 (e.g., one or more (or all) side surfaces 146S of the upper UBM pad 146), and the connection member 150 may be in contact with one or more (or all) side surfaces 147S of the UBM pad 147. Accordingly, the contact area between the UBM pad 147 and the connection member 150 may increase, and thus, the electrical characteristics (e.g., electrical reliability) of the semiconductor package 10 may be improved while enabling reduced size of the semiconductor package 10.

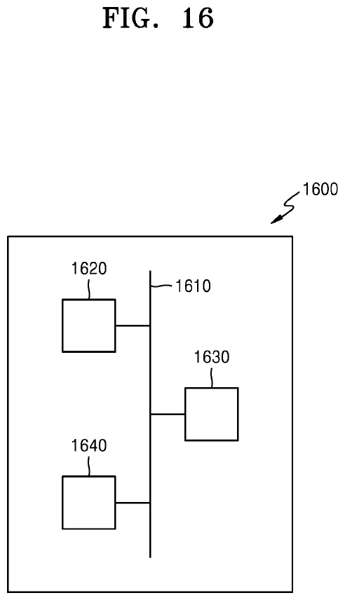

FIG. 16 is a schematic view of an electronic device according to some example embodiments.

Referring to FIG. 16, an electronic device 1600 may include a processor 1620 (e.g., a central processing unit or CPU), a memory 1630 (e.g., a solid state drive (SSD) storage device), and a power supply 1640 electrically connected to each other through a bus 1610. The memory 1630, which may be a non-transitory computer readable medium (e.g., a SSD storage device), may store a program of instructions. The processor 1620 (e.g., a CPU) may execute the stored program of instructions to perform one or more functions. The processor 1620 may be configured to generate an output based on such as processing. One or more of the processor 1620, the memory 1630, or the power supply 1640 may include a semiconductor package 10 according to any of the example embodiments, including for example the semiconductor package 10 as shown in FIG. 1.

The electronic device 1600 and/or any portion thereof (e.g., processor 1620, memory 1630, etc.) may include processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), or the like. As an example, the processing circuitry may include a non-transitory computer readable storage device. The processor 1620 (e.g., a central processing unit or CPU) may, for example, control an operation of the electronic device 1600, for example based on executing an instruction program stored at the memory 1630 (e.g., a solid-state drive (SSD) storage device).

While the inventive concepts have been particularly shown and described with reference to embodiments thereof, it will be understood that various changes in form and details may be made therein without departing from the spirit and scope of the following claims.

What is claimed is:

1. A semiconductor package, comprising:
an interposer;
a semiconductor chip on the interposer;
an under bump metal (UBM) pad between the interposer and the semiconductor chip, the UBM pad including an upper UBM pad and a lower UBM pad; and
a connection member between the UBM pad and the semiconductor chip,
wherein the connection member is in contact with one or more side surfaces of the UBM pad and is in contact with the interposer.

2. The semiconductor package of claim 1, further comprising:
a plating layer between the upper UBM pad and the connection member.

3. The semiconductor package of claim 1, further comprising:
an adhesion layer and a seed layer, both the adhesion layer and the seed layer between the UBM pad and the interposer,
wherein the connection member is in contact with at least one of the adhesion layer or the seed layer.

4. The semiconductor package of claim 3, wherein the adhesion layer and the seed layer extend conformally on a lower surface of the lower UBM pad, a side surface of the lower UBM pad, and a lower surface of the upper UBM pad.

5. The semiconductor package of claim 3, wherein a side surface of the upper UBM pad, a side surface of the adhesion layer, and a side surface of the seed layer are aligned in a vertical direction, the vertical direction perpendicular to a main surface of the interposer.

6. The semiconductor package of claim 1, wherein
the interposer includes a plurality of conductive line patterns and a plurality of conductive via patterns, and
the plurality of conductive via patterns each have a tapered shape with a horizontal width decreasing with increasing distance from the semiconductor chip, the horizontal width extending in a horizontal direction parallel to a main surface of the interposer.

7. The semiconductor package of claim 1, wherein a horizontal width of the upper UBM pad is greater than a horizontal width of the lower UBM pad.

8. The semiconductor package of claim 1, wherein an upper surface of the upper UBM pad includes a rounded curved surface.

9. A method of manufacturing a semiconductor package, the method comprising:
forming an interposer;
forming an under bump metal (UBM) pad on the interposer;
forming a plating layer on the UBM pad; and
attaching a connection member onto the UBM pad,
wherein the plating layer is in contact with one or more side surfaces of the UBM pad.

10. The method of claim 9, wherein the connection member is in contact with the one or more side surfaces of the UBM pad.

11. The method of claim 9, wherein the plating layer is in contact with the interposer.

12. The method of claim 9, wherein the forming of the UBM pad includes
forming an adhesion layer and a seed layer on the interposer;
forming a mask pattern on the seed layer; and
forming the UBM pad on the seed layer.

13. The method of claim 12, wherein the forming of the plating layer is performed after removing the mask pattern.

14. The method of claim 9, further comprising:
forming an additional plating layer on the UBM pad, the additional plating layer in contact with the UBM pad.

15. The method of claim 9, wherein the forming of the plating layer is performed based on performing an electroless plating method.

16. A method of manufacturing a semiconductor package, the method comprising:
forming an interposer;
forming an under bump metal (UBM) pad on the interposer;
mounting a semiconductor chip on the UBM pad; and
forming a molding layer on the interposer such that the molding layer covers one or more side surfaces of the semiconductor chip,
wherein the mounting of the semiconductor chip on the UBM pad includes
forming a plating layer on the UBM pad, and
attaching a connection member onto the UBM pad, and
wherein the plating layer is in contact with one or more side surfaces of the UBM pad.

17. The method of claim 16, wherein
the forming of the UBM pad includes conformally forming an adhesion layer and a seed layer on the interposer, and
the plating layer is in contact with both of the adhesion layer and the seed layer.

18. The method of claim 16, further comprising:
forming an additional plating layer on the UBM pad, the additional plating layer in contact with the UBM pad,
wherein the additional plating layer includes a material different from the plating layer.

19. The method of claim 16, wherein the connection member includes a material of the plating layer.

20. The method of claim 16, wherein the forming of the plating layer is performed based on performing an immersion plating method.
